(19) United States
(12) Patent Application Publication
(10) Pub. No.: US 2023/0137750 A1
(43) Pub. Date: May 4, 2023

(54) METHOD FOR PRODUCING POWER SEMICONDUCTOR DEVICE WITH HEAT DISSIPATING CAPABILITY

(71) Applicant: National Yang Ming Chiao Tung University, Hsinchu City (TW)

(72) Inventor: Ray-Hua HORNG, Taichung City (TW)

(21) Appl. No.: 17/859,614

(22) Filed: Jul. 7, 2022

(30) Foreign Application Priority Data
Nov. 2, 2021 (TW) 110140786

(51) Int. Cl. H01L 29/20; H01L 21/02; H01L 29/51

(52) U.S. Cl. CPC H01L 29/2003; H01L 21/02458; H01L 21/02433; H01L 29/511; H01L 29/517

(57) ABSTRACT

A method for producing a power semiconductor device with heat dissipating capability includes epitaxially growing a GaN-based buffer layer on a first surface of a sapphire substrate, epitaxially growing a Ga₂O₃ semiconductor layer on the GaN-based buffer layer, forming a source and a drain, a gate dielectric layer, a first gate, an insulator layer, and a metal adhesive layer in sequence, removing part of the metal adhesive layer, the insulator layer, and the gate dielectric layer to expose one of the source and the drain, forming a heat sink which covers the metal adhesive layer, the insulator layer, the gate dielectric layer, and the one of the source and the drain, and conducting a laser lift-off process through a second surface of the sapphire substrate to remove the sapphire substrate and the GaN-based buffer layer.

### CROSS-REFERENCE TO RELATED APPLICATION

This application claims priority of Taiwanese Invention Patent Application No. 110140786, filed on Nov. 2, 2021.

### FIELD

The disclosure relates to a power semiconductor device, more particularly to a method for producing a power semiconductor device with heat dissipating capability.

### BACKGROUND

The first-generation semiconductor (the material of which is silicon (Si)) has an energy gap of 1.17 eV, making it suitable for power semiconductor devices. With the evolution of the integrated circuit manufacturing process, semiconductor devices have become lighter, thinner, shorter and smaller. The second-generation semiconductor (the material of which may be gallium arsenide (GaAs) and indium phosphide (InP)) and the third-generation semiconductor (the material of which may be silicon carbide (SiC) and gallium nitride (GaN)) have also been developed one after another.

Recently, the fourth-generation semiconductor (the material of which is gallium oxide (Ga₂O₃)) has an energy gap up to 4.9 eV and has received increased interest from power semiconductor device industries. Although Ga₂O₃ is suitable to be applied to power semiconductor devices, the thermal conductivity (κ) of Ga₂O₃ is low, such that the power semiconductor devices made thereof generate high heat during operation. Therefore, the power semiconductor devices made of Ga₂O₃ have severe heat dissipation problems.

At present, several techniques are applied to improve the heat dissipation of the power semiconductor devices made of Ga₂O₃. As reported in Zhou, H. et al. (2017), ACS Omega, 2:7723-7729, Zhou, H. et al. have disclosed that the self-heating effect is a severe issue for high-power semiconductor devices, which degrades the electron mobility and saturation velocity, and which also affects the device reliability. Zhou, H. et al. have further demonstrated that by utilizing a more thermally conductive sapphire substrate rather than a SiO₂/Si substrate, the temperature rise above room temperature of β-Ga₂O₃ on the insulator field-effect transistor can be reduced by a factor of 3 and thereby the self-heating effect is significantly reduced.

FIG. 1 is a schematic diagram illustrating the method disclosed by Zhou, H. et al. First, β-Ga₂O₃ nanomembranes are mechanically exfoliated from a Sn-doped (2̅01) β-Ga₂O₃ bulk substrate's edge cleavage through a scotch tape method (not shown in FIG. 1). Next, referring to FIG. 1, the β-Ga₂O₃ nanomembranes are respectively transferred to a SiO₂/p⁺⁺ Si substrate 111 and a sapphire substrate 121 that are cleaned with acetone for 24 hour prior to the transfer, so as to obtain corresponding β-Ga₂O₃ 2D flakes 112, 122. Thereafter, a corresponding one of Ti/Al/Au sources 113, 123, a corresponding one of Ti/Al/Au drains 114, 124, a corresponding one of Al₂O₃ gate dielectric layers 115, 125, and a corresponding one of Ni/Au gate electrodes 116, 126 are formed on each of the β-Ga₂O₃ 2D flakes 112, 122 using electron-beam lithography (EBL), photoresist stripping, and thin film deposition techniques in sequence, thereby obtaining a first β-Ga₂O₃ thin-film transistor 11 and a second β-Ga₂O₃ thin-film transistor 12. Both thermoreflectance characterization and simulation verify that the thermal resistance on the second β-Ga₂O₃ thin-film transistor 12 having the sapphire substrate 121 is less than ⅓ of that on the first β-Ga₂O₃ thin-film transistor 11 having the SiO₂/p⁺⁺ Si substrate 111.

Using the sapphire substrate 121 as the substrate of the second β-Ga₂O₃ thin-film transistor 12 might solve the problem arising from the self-heating effect of the power semiconductor device. However, the thermal conductivity (κ) of sapphire is only about 40 W/m·K, so sapphire cannot effectively solve the problem of heat dissipation.

### SUMMARY

Accordingly, the present disclosure provides a method for producing a power semiconductor device with heat dissipating capability, which can alleviate at least one of the drawbacks of the prior art, and which includes:
(a) epitaxially growing a GaN-based buffer layer having a hexagonal crystal structure on a first surface of a sapphire substrate;
(b) epitaxially growing a Ga₂O₃ semiconductor layer having a monoclinic crystal structure on the GaN-based buffer layer;
(c) forming a source region and a drain region on two opposite sides of the Ga₂O₃ semiconductor layer;
(d) forming a source and a drain that are respectively connected to the source and drain regions of the Ga₂O₃ semiconductor layer;
(e) forming a gate dielectric layer covering the Ga₂O₃ semiconductor layer, the source, and the drain;
(f) forming a first gate on the gate dielectric layer;
(g) forming an insulator layer on the first gate;
(h) forming a metal adhesive layer on the insulator layer;
(i) removing part of the metal adhesive layer, the insulator layer, and the gate dielectric layer to expose one of the source and the drain;
(j) conducting an electroforming process to form a heat sink which covers the metal adhesive layer, the insulator layer, the gate dielectric layer, and the one of the source and drain; and
(k) conducting a laser lift-off process through a second surface of the sapphire substrate opposite to the first surface of the sapphire substrate to remove the sapphire substrate and the GaN-based buffer layer, so as to expose surfaces of the Ga₂O₃ semiconductor layer, the source, and the drain that are opposite to the gate dielectric layer.

The present disclosure provides another method for producing a power semiconductor device with heat dissipating capability, which can alleviate at least one of the drawbacks of the prior art, and which includes:
(a) epitaxially growing a GaN-based buffer layer having a hexagonal crystal structure on a first surface of a sapphire substrate;
(b) epitaxially growing a Ga₂O₃ semiconductor layer having a monoclinic crystal structure on the GaN-based buffer layer;
(c′) forming a metal adhesive layer on the Ga₂O₃ semiconductor layer;
(d′) conducting a wafer bonding process to form a heat sink on the metal adhesive layer; and
(e′) conducting a laser lift-off process through a second surface of the sapphire substrate opposite to the first surface of the sapphire substrate to remove the sapphire substrate and the GaN-based buffer layer, so as to expose a surface of the Ga₂O₃ semiconductor layer opposite to the metal adhesive layer.

### BRIEF DESCRIPTION OF THE DRAWINGS

Other features and advantages of the disclosure will become apparent in the following detailed description of the embodiments with reference to the accompanying drawings, of which:

FIG. 1 is a schematic sectional view illustrating two β-Ga₂O₃ thin-film transistors disclosed in Zhou, H. et al. (2017), supra;

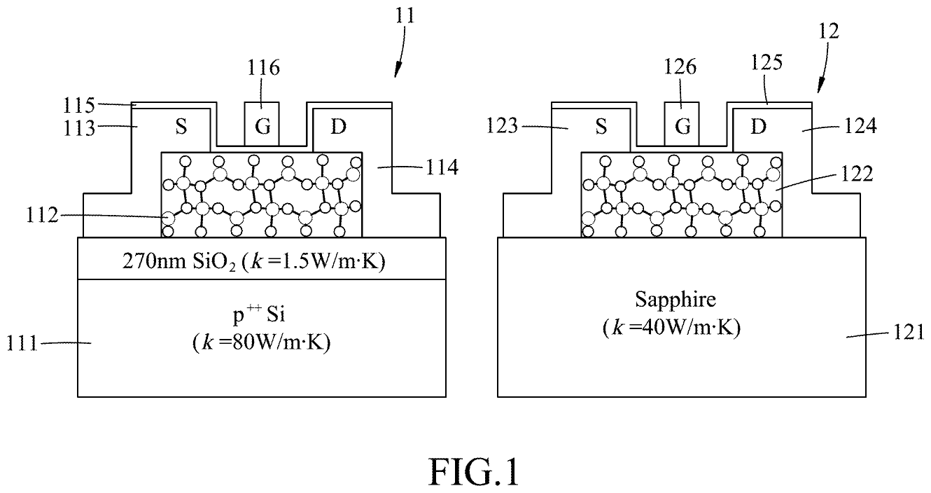

FIG. 2 is a schematic sectional view illustrating steps (a) to (c) of a first embodiment of a method for producing a power semiconductor device with heat dissipating capability according to the present disclosure;

FIG. 3 is a schematic sectional view illustrating steps (d) to (e) of the first embodiment;

FIG. 4 is a schematic sectional view illustrating steps (f) to (g) of the first embodiment;

FIG. 5 is a schematic sectional view illustrating steps (h) to (i) of the first embodiment;

FIG. 6 is a schematic sectional view illustrating steps (j) to (k) of the first embodiment;

FIG. 7 is a schematic sectional view illustrating steps (1) to (n) of the first embodiment;

FIG. 8 is a schematic sectional view illustrating steps (a) to (b) of a second embodiment of a method for producing a power semiconductor device with heat dissipating capability according to the present disclosure;

FIG. 9 is a schematic sectional view illustrating steps (c′) to (d′) of the second embodiment; and

FIG. 10 is a schematic sectional view illustrating step (e′) of the second embodiment.

### DETAILED DESCRIPTION

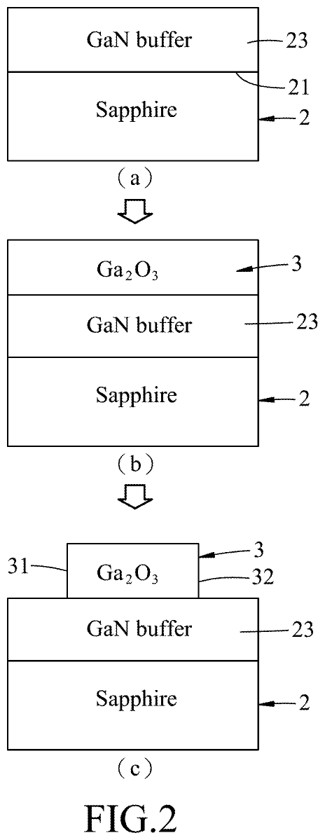

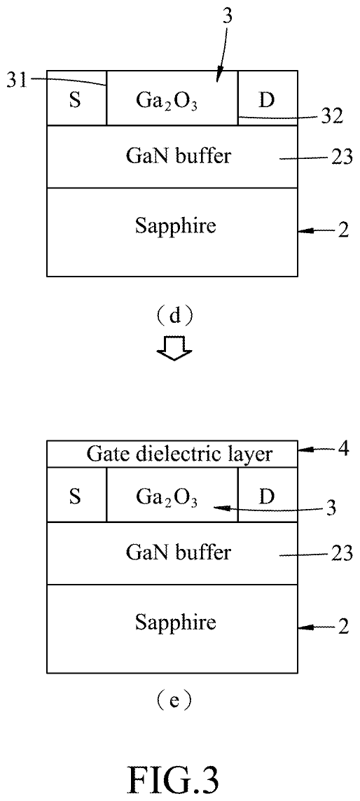

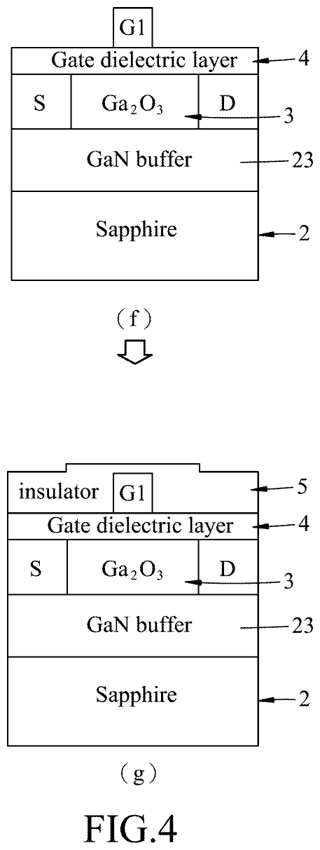

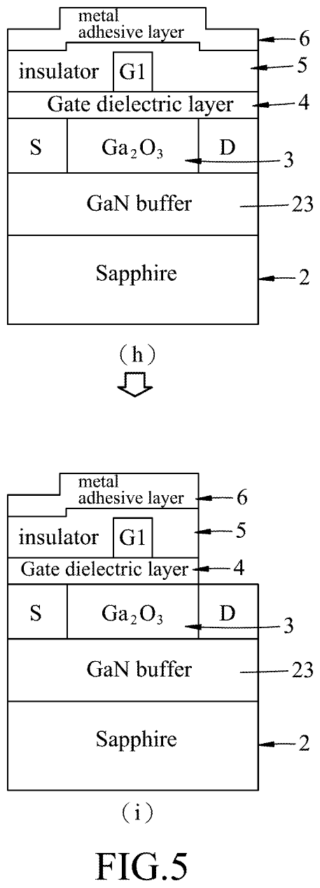

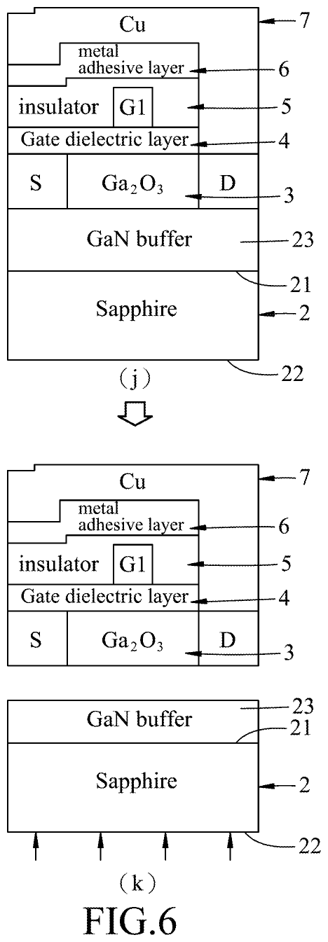

Referring to FIGS. 2 to 6, a first embodiment of a method for heat dissipation of a power semiconductor device according to the present disclosure includes:
(a) epitaxially growing a GaN-based buffer layer 23 having a hexagonal crystal structure on a first surface 21 of a sapphire substrate 2;
(b) epitaxially growing a Ga₂O₃ semiconductor layer 3 having a monoclinic crystal structure on the GaN-based buffer layer 23;
(c) forming a source region 31 and a drain region 32 on two opposite sides of the Ga₂O₃ semiconductor layer 3;
(d) forming a source S and a drain D that are respectively connected to the source region 31 and the drain region 32 of the Ga₂O₃ semiconductor layer 3;
(e) forming a gate dielectric layer 4 covering the Ga₂O₃ semiconductor layer 3, the source S, and the drain D;
(f) forming a first gate G1 on the gate dielectric layer 4;
(g) forming an insulator layer 5 on the first gate G1;
(h) forming a metal adhesive layer 6 on the insulator layer 5;
(i) removing part of the metal adhesive layer 6, the insulator layer 5, and the gate dielectric layer 4 to expose one of the source S and drain D;
(j) conducting an electroforming process to form a heat sink 7 which covers the metal adhesive layer 6, the insulator layer 5, the gate dielectric layer 4, and the one of the source S and the drain D; and
(k) conducting a laser lift-off process through a second surface 22 of the sapphire substrate 2 opposite to the first surface 21 of the sapphire substrate 2 to remove the sapphire substrate 2 and the GaN-based buffer layer 23, so as to expose surfaces of the Ga₂O₃ semiconductor layer 3, the source S, and the drain D that are opposite to the gate dielectric layer 4.

The details of the steps are described below.

In step (a) of this embodiment, the sapphire substrate 2 has a thermal conductivity (κ) of about 40 W/m·K.

In step (a) of this embodiment, the GaN-based buffer layer 23 is epitaxially grown on the first surface 21 of the sapphire substrate 2 through metal-organic chemical vapor deposition MOCVD using trimethylgallium (TMG, Ga(CH₃)₃) and N₂ as precursors.

In step (b) of this embodiment, the Ga₂O₃ semiconductor layer 3 is epitaxially grown on the GaN-based buffer layer 23 through MOCVD using TMG and O₂ as precursors.

In step (c) of this embodiment, the source region 31 and the drain region 32 may be formed by conducting a patterning process to remove part of the Ga₂O₃ semiconductor layer 3 and expose the GaN-based buffer layer 23. Optionally, after the patterning process, the two opposite sides of the Ga₂O₃ semiconductor layer 3 may be further subjected to an ion implantation process to form a high doping concentration.

In step (d) of this embodiment, each of the source S and the drain D is a Ti/Al/Au contact electrode made by sputtering.

In step (e) of this embodiment, the gate dielectric layer 4 is made of Al₂O₃.

In step (f) of this embodiment, the first gate G1 is a Ni/Au gate made by sputtering.

In step (g) of this embodiment, the insulator layer 5 is formed on the first gate G1 to cover the first gate G1 and the gate dielectric layer 4.

In step (i) of this embodiment, after removing the part of the metal adhesive layer 6, the insulator layer 5, and the gate dielectric layer 4, the drain D is exposed.

The heat sink 7 may be made of a metal selected from the group consisting of silver (Ag), copper (Cu), gold (Au), aluminum (Al), sodium (Na), molybdenum (Mo), tungsten (W), zinc (Zn), nickel (Ni), and combinations thereof. For instance, the heat sink 7 is made of copper (Cu) having a thermal conductivity (κ) of 401 W/m·K.

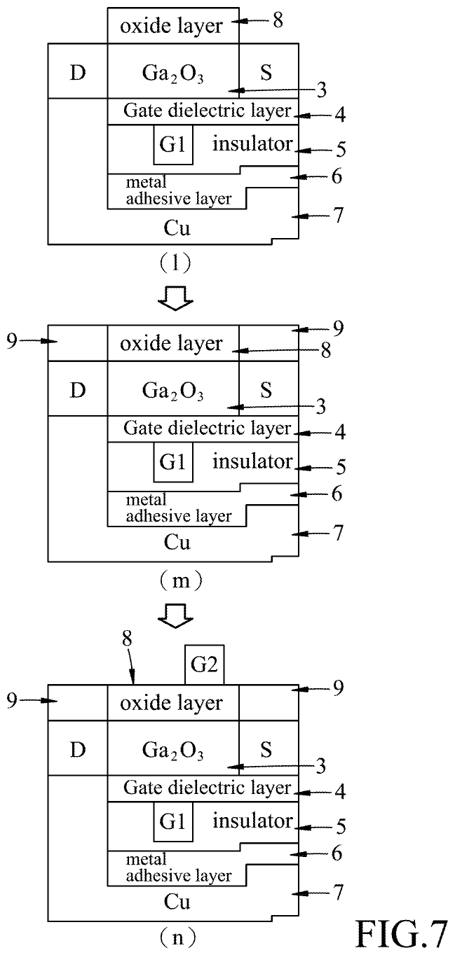

In this embodiment, referring to FIG. 7, the production method may further include:
(l) forming an oxide layer 8 on the exposed surface of the Ga₂O₃ semiconductor layer 3;
(m) forming an electrode pad 9 on the exposed surface of a respective one of the source S and the drain D; and
(n) forming a second gate G2 on the oxide layer 8, the second gate G2 being configured to be a field plate.

The second gate G2 may be made of Ti/Au to reduce hot electrons and the leakage current effect.

In this embodiment, since the Ga₂O₃ semiconductor layer 3 is epitaxially grown, through MOCVD, on the GaN-based buffer layer 23 that is grown on the first surface 21 of the sapphire substrate 2, the lattice mismatch between the GaN-based buffer layer 23 having a hexagonal crystal structure and the Ga₂O₃ semiconductor layer 3 having a monoclinic crystal structure is low. By virtue of the epitaxial growth process, the threading dislocation density of the Ga₂O₃ semiconductor layer 3 can be reduced, so that the Ga₂O₃ semiconductor layer 3 has excellent epitaxial quality.

Moreover, the sapphire substrate 2 having a thermal conductivity (κ) of about 40 W/m·K is removed by a laser lift-off process, and copper (Cu) having a thermal conductivity (κ) of 401 W/m·K is used to form the heat sink 7 above the Ga₂O₃ semiconductor layer 3, thereby further reducing the thermal resistance and improving the heat dissipation effect.

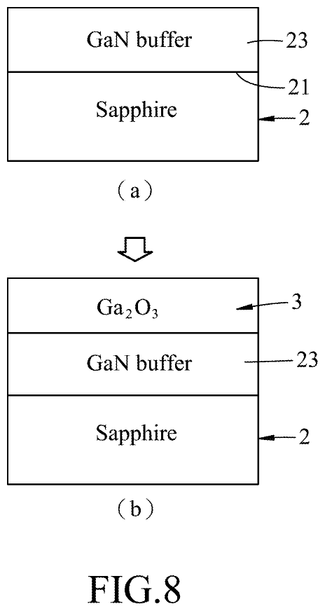

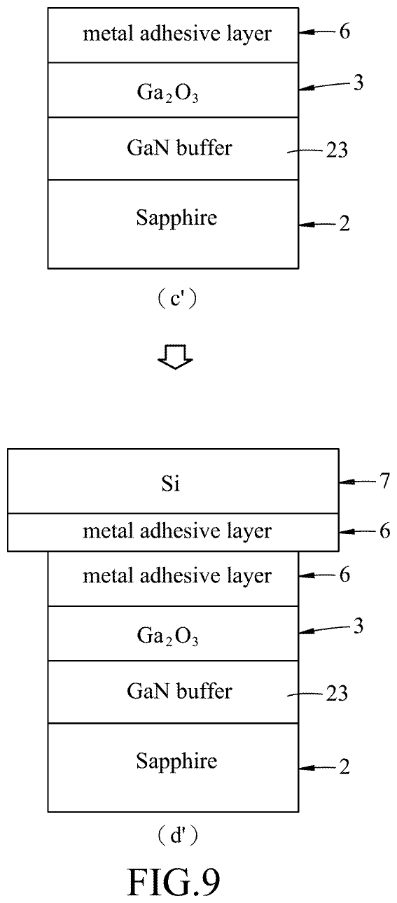

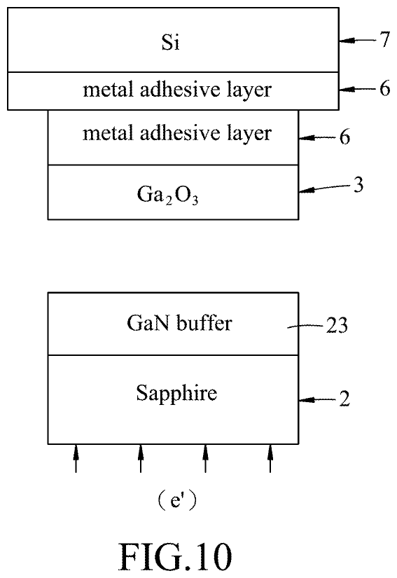

In addition, referring to FIGS. 8 to 10, a second embodiment of the production method according to the present disclosure includes:
(a) epitaxially growing a GaN-based buffer layer 23 having a hexagonal crystal structure on a first surface 21 of a sapphire substrate 2;
(b) epitaxially growing a Ga₂O₃ semiconductor layer 3 having a monoclinic crystal structure on the GaN-based buffer layer 23;
(c′) forming a metal adhesive layer 6 on the Ga₂O₃ semiconductor layer 3;
(d′) conducting a wafer bonding process to form a heat sink 7 on the metal adhesive layer 6; and
(e′) conducting a laser lift-off process to remove the sapphire substrate 2 and the GaN-based buffer layer 23, so as to expose a surface of the Ga₂O₃ semiconductor layer 3 opposite to the metal adhesive layer.

In the second embodiment, the heat sink 7 may be made of a material selected from the group consisting of a silicon wafer, a silicon carbide wafer, an aluminum nitride substrate, and combinations thereof.

In the second embodiment, the production method may further include:
(f′) forming a source region 31 and a drain region 32 on two opposite sides of the Ga₂O₃ semiconductor layer 3;
(g′) forming a source S and a drain D respectively on the source region 31 and the drain region 32 of the Ga₂O₃ semiconductor layer 3, so that the source S and the drain D are respectively connected to the opposite sides of the Ga₂O₃ semiconductor layer 3;
(h′) forming a gate dielectric layer 4 covering the exposed surface of the Ga₂O₃ semiconductor layer 3, the source S, and the drain D;
(i′) forming a first gate G1 on the gate dielectric layer 4; and
(j′) forming an insulator layer 5 on the first gate G1.

The formation of the source region 31 and the drain region 32, the formation of the source S and the drain D, and the formation of the gate dielectric layer 4, the first gate G1, and the insulator layer 5 in the second embodiment may be similar to those described for the first embodiment.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A method for producing a power semiconductor device with heat dissipating capability, comprising:
(a) epitaxially growing a GaN-based buffer layer having a hexagonal crystal structure on a first surface of a sapphire substrate;
(b) epitaxially growing a Ga₂O₃ semiconductor layer having a monoclinic crystal structure on said GaN-based buffer layer;
(c) forming a source region and a drain region on two opposite sides of said Ga₂O₃ semiconductor layer;
(d) forming a source and a drain that are respectively connected to said source region and said drain region of said Ga₂O₃ semiconductor layer;
(e) forming a gate dielectric layer covering said Ga₂O₃ semiconductor layer, said source, and said drain;
(f) forming a first gate on said gate dielectric layer;
(g) forming an insulator layer on said first gate;
(h) forming a metal adhesive layer on said insulator layer;
(i) removing part of said metal adhesive layer, said insulator layer, and said gate dielectric layer to expose one of said source and said drain;
(j) conducting an electroforming process to form a heat sink which covers said metal adhesive layer, said insulator layer, said gate dielectric layer, and said one of said source and said drain; and
(k) conducting a laser lift-off process through a second surface of said sapphire substrate opposite to said first surface of said sapphire substrate to remove said sapphire substrate and said GaN-based buffer layer, so as to expose surfaces of said Ga₂O₃ semiconductor layer, said source, and said drain that are opposite to said gate dielectric layer.

2. The method according to claim 1, wherein in step (j), said heat sink is made of a metal selected from the group consisting of silver, copper, gold, aluminum, sodium, molybdenum, tungsten, zinc, nickel, and combinations thereof.

3. The method according to claim 1, further comprising:
(l) forming an oxide layer on said exposed surface of said Ga₂O₃ semiconductor layer;
(m) forming an electrode pad on said exposed surface of a respective one of said source and said drain; and
(n) forming a second gate on said oxide layer, said second gate being configured to be a field plate.

4. A method for producing a power semiconductor device with heat dissipating capability, comprising:
(a) epitaxially growing a GaN-based buffer layer having a hexagonal crystal structure on a first surface of a sapphire substrate;
(b) epitaxially growing a Ga₂O₃ semiconductor layer having a monoclinic crystal structure on said GaN-based buffer layer;
(c′) forming a metal adhesive layer on said Ga₂O₃ semiconductor layer;
(d′) conducting a wafer bonding process to form a heat sink on said metal adhesive layer; and
(e′) conducting a laser lift-off process through a second surface of said sapphire substrate opposite to said first surface of said sapphire substrate to remove said sapphire substrate and said GaN-based buffer layer, so as to expose a surface of said Ga₂O₃ semiconductor layer opposite to the metal adhesive layer.

5. The method according to claim 4, wherein in step (d′), said heat sink is made of a material selected from the group consisting of a silicon wafer, a silicon carbide wafer, an aluminum nitride substrate, and combinations thereof.

6. The method according to claim 4, further comprising:
(f′) forming a source region and a drain region on two opposite sides of said Ga₂O₃ semiconductor layer;
(g′) forming a source and a drain that are respectively connected to said source region and said drain region of said Ga₂O₃ semiconductor layer;
(h′) forming a gate dielectric layer covering said exposed surface of said Ga₂O₃ semiconductor layer, said source, and said drain;
(i′) forming a first gate on said gate dielectric layer; and
(j′) forming an insulator layer on said first gate.
